(19) United States
(12) Patent Application Publication
(10) Pub. No.: US 2025/0157927 A1
(43) Pub. Date: May 15, 2025

(54) LOW RESISTANCE SIGNAL TRANSDUCTION ENABLED BY HIGH EFFICIENCY COPPER FEEDTHROUGHS

(71) Applicant: Taiwan Semiconductor Manufacturing Company, LTD., Hsinchu (TW)

(72) Inventors: Chien-Han Chen, Nantou (TW); Shih-Yu Chang, Yunlin (TW); Chien-Chih Chiu, Xinying (TW)

(21) Appl. No.: 18/388,630

(22) Filed: Nov. 10, 2023

(51) Int. Cl. H01L 23/528; H01L 21/768; H01L 23/48; H01L 23/522; H01L 23/532

(52) U.S. Cl. CPC H01L 23/5286; H01L 21/7684; H01L 21/76898; H01L 23/481; H01L 23/5226; H01L 23/53238

(57) ABSTRACT

In fabricating an integrated circuit, a device layer is formed. A metallization stack is formed on a front side of the device layer, and a back side power distribution network is formed on a back side of the device layer. Copper vias are formed which pass through the device layer and contact at least one patterned metal layer of the metallization stack. The copper vias are formed by a damascene process. At least one signal transmission conductor may be formed, which is disposed on the back side of the device layer and is electrically connected with the copper vias. In a dual damascene variant, trenches are etched in the at least one back side dielectric layer prior to the electroplating, and the electroplating also fills the trenches to form a patterned metal layer of the back side power distribution network and/or to form the at least one signal transmission conductor.

### BACKGROUND

The following relates to the semiconductor device arts, integrated circuit (IC) arts, and related arts.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 diagrammatically illustrates a sectional view of an IC including at least one signal transmission conductor disposed on a back side of a device layer of the IC.

FIGS. 2A, 2B, 2C, 2D, and 2E diagrammatically illustrate sectional views of successive stages of fabrication of an IC including at least one signal transmission conductor disposed on a back side of a device layer of the IC.

FIG. 3 diagrammatically illustrates an isolation perspective view of a signal transmission conductor disposed on a back side of a device layer of an IC.

FIGS. 4A, 4B, 4C, 4D, 4E, 4F, 4G, 4H, and 4I diagrammatically illustrate sectional views of successive stages of fabrication of a copper via by a damascene process according to an embodiment for use in connecting with a signal transmission conductor disposed on a back side of a device layer of an IC.

FIGS. 5A, 5B, 5C, 5D, 5E, 5F, 5G, 5H, and 5I diagrammatically illustrate sectional views of successive stages of fabrication of a copper via by a dual damascene process according to an embodiment for use in connecting with a signal transmission conductor disposed on a back side of a device layer of an IC.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A typical integrated circuit (IC) includes a device layer formed during front end-of-line (FEOL) processing, and a metallization stack formed during back end-of-line (BEOL) processing. The device layer typically includes various semiconductor devices, such as field effect transistors (FETs), diodes, photodiodes, and so forth, fabricated on or in a front surface of a semiconductor substrate made of silicon (e.g., a silicon wafer) or made of another semiconductor material. The devices of the device layer are formed using various semiconductor processing operations such as dopant diffusion and/or implantation, etching, material deposition, and/or so forth. Thereafter, a metallization stack is formed on the front side of the substrate, and more particularly on the device layer. In typical BEOL processing, each layer of the metallization stack is formed by deposition of intermetal dielectric (IMD) layer, opening and filling via openings in the IMD layer to from vias (i.e., feed-throughs) passing through the IMD layer, depositing a metal layer on the IMD layer and patterning the metal layer to form a patterned metal layer. The vias through first IMD layer contact terminals of devices of the device layer.

Traditional signal transmission is thus achieved by inputting power into a device of the device layer and then transmitting the signal to another device of the device layer through BEOL wiring of the metallization stack disposed on the front side of the substrate. The signal may pass through many patterned metal layers of the metallization stack, and may pass through interfaces between different materials. For example, the vias may be made of tungsten (W) while the patterned metal layers may be copper, and other types of materials such as aluminum may also be incorporated. Consequently, utilization of power for signal transmission through the front side metallization stack can be inefficient and impractical, resulting in slower signal transmission speed, resistive power loss in long front side transmission paths, and galvanic losses at interfaces between different materials.

These issues with signal handling become increasingly problematic as IC's are further miniaturized and implement increasingly complex device circuitry. Miniaturization can reduce signal path length, but with higher device quantities and densities the amount of wiring in the metallization stack increases, which can require additional patterned metal layers that lengthen path lengths. In some modern ICs the metallization stack may include more than a dozen patterned metal layers, with signal loss occurring each time the signal passes between layers. Larger IC circuitry area can also dictate longer path lengths. If an IC occupies a square area of dimension N² then as N increases the maximum possible distance between a pair of devices increases. Layout design can mitigate this by avoiding connections between devices near opposite edges of the IC area, but may not be able to completely long signal connections.

A further challenge is power delivery to the IC. This is conventionally also done through the front side metallization stack, thus further increasing the density and complexity of wiring implemented in the stack. This challenge can be mitigated by use of a back side power distribution network (BS-PDN) for providing the electrical power. The BS-PDN includes conductors formed on the back side of the substrate, sometimes called rails, which deliver the electrical power. Use of a BS-PDN advantageously separates the power delivery at substrate back side from the signal transmission via the front side metallization stack. However, the BS-PDN does not address other signal transmission challenges created by IC miniaturization, namely long signal paths crossing multiple materials (copper/tungsten interfaces, for example).

In approaches disclosed herein, signal transmission paths are provided on the back side of the substrate. These back side signal transmission paths can be in addition to the BS-PDN, and are supplemental to the usual front side signal transmission via the front side metallization stack. The back side signal transmission paths are contemplated for use for signals that are especially susceptible to the transmission challenges of long signal paths crossing multiple materials. For example, high-current signals can experience higher resistive (IR) power loss P=I²R, where I is the magnitude of the electric current, R is the resistance of the signal path, and P is the resistive power loss. Hence, signal power loss increases with the square of the electric current. Similarly, high frequency signals can experience higher power loss due to the skin effect, where at higher frequencies the electric current is principally carried at the surface of the conductor. Signal paths between more distant pairs of devices will also experience higher power loss. For example, a signal carried from a device near one edge of the IC area to a device near an opposite edge of the IC area will have a longer overall signal path and higher I²R loss.

The back side signal transmission paths disclosed herein are suitably used to transmit signals which are expected to have higher power loss for such reasons, while the conventional front side metallization stack is used to transmit other signals.

Moreover, the back side signal transmission paths disclosed herein are designed to minimize resistive signal loss while being fabricated by processes that are highly compatible with existing IC fabrication workflows. For example, the disclosed back side signal transmission paths connect with patterned metal layer(s) of the front side metallization stack using all-copper vias (i.e., all-copper feed-throughs) formed by a damascene process that entails as few as a single additional mask step and wet and/or dry etching to form the via openings that are filled by electroplating and chemical mechanical polishing (CMP). In some embodiments, a dual damascene process is employed which also advantageously forms a patterned metal layer of the back side power distribution network, and/or forms the back side signal transmission conductor(s). This approach advantageously eliminates interfaces between different materials, as the back side signal transmission paths are all-copper.

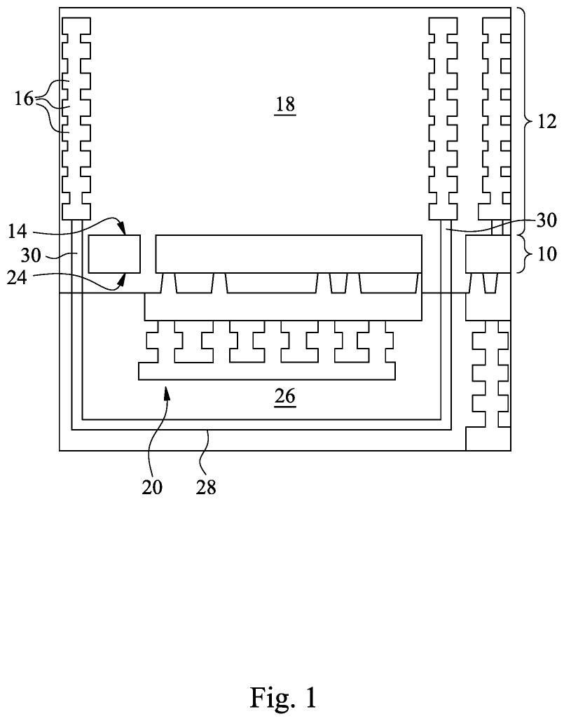

With reference to FIG. 1, an integrated circuit includes a device layer 10 comprising a plurality of electronic devices (not shown individually in FIG. 1). The device layer 10 is typically formed during FEOL processing. A metallization stack 12 is disposed on a front side 14 of the device layer 10. The metallization stack 12 includes a plurality of patterned metal layers 16 spaced apart by intermetal dielectric material 18. The metallization stack 12 is typically formed in BEOL processing, and electrically interconnects the electronic devices of the device layer 10. A back side power distribution network 20 is disposed on a back side 24 of the device layer 10, and is connected to deliver electrical power to the plurality of semiconductor devices of the device layer 10. The back side power distribution network 20 is embedded or disposed in a back side dielectric material 26. The illustrative back side power distribution network 20 includes a lower portion 26-1 that makes electrical connection with the semiconductor devices of the device layer 10, and an upper portion 26-2 forming power distribution rails or the like. In a nonlimiting illustrative example, the lower portion 26-1 comprises tungsten while the upper portion 26-2 comprises copper, although other materials are contemplated. The back side dielectric material 26 may in some nonlimiting embodiments be a low-k dielectric material having a dielectric constant K that is less than the dielectric constant of silicon dioxide (SiO₂, κ=3.9). For example, the back side dielectric material 26 may in some nonlimiting embodiments be a low-k dielectric material such as fluorine-doped silicon dioxide, an organosilicate glass (OSG), various combinations thereof, and/or so forth.

At least one signal transmission conductor 28 is also disposed on the back side 24 of the device layer 10 and embedded or disposed in the dielectric material 26. The at least one signal transmission conductor 28 serves to transmit electrical signals between devices of the device layer 10. Copper vias (i.e., copper feed-throughs) 30 pass through the device layer 10. The copper vias 30 electrically connect the at least one signal transmission conductor 26 with at least one patterned metal layer 16 of the metallization stack 12.

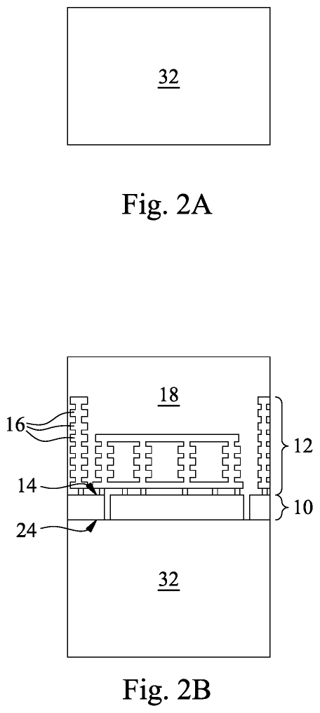

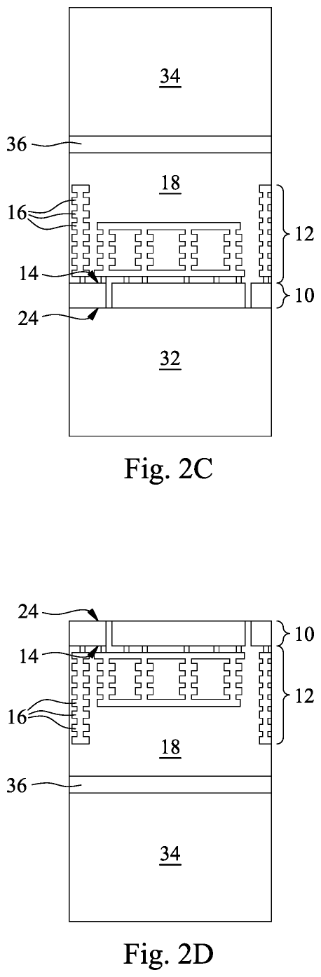

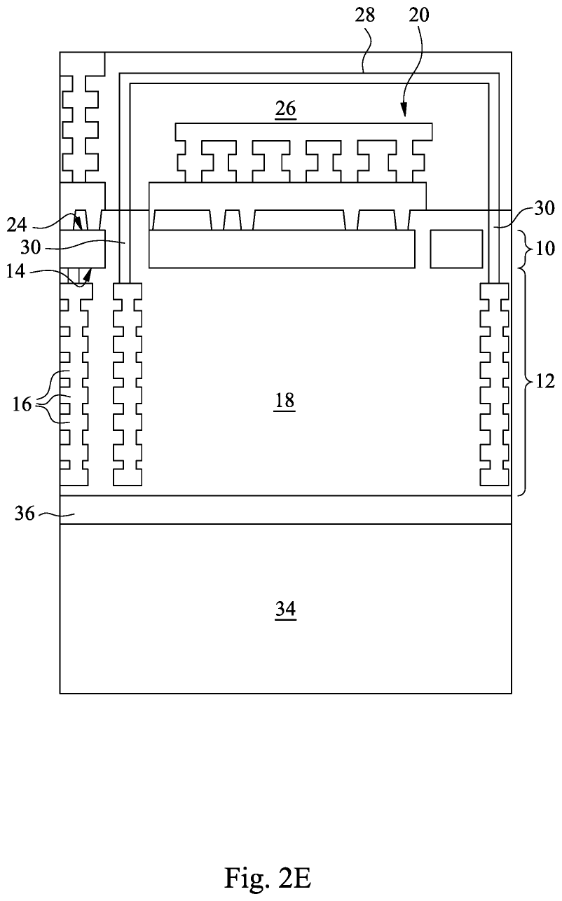

With reference now to FIGS. 2A-2E, a suitable approach for fabricating the IC of FIG. 1 is described. FIGS. 2A-2E diagrammatically illustrate sectional views of successive stages of fabrication of the IC. FIG. 2A illustrates a substrate 32, which may by way of some nonlimiting illustrative examples comprise a silicon wafer, a silicon-on-insulator (SOI) wafer, a silicon-germanium wafer, a gallium arsenide wafer, or another semiconductor substrate. Front end-of-line (FEOL) processing is performed to form semiconductor devices such as field effect transistors (FETs), diodes, photodiodes, resistors, capacitors, various combinations thereof, and/or so forth on or in the semiconductor wafer 32. These semiconductor devices make up the device layer 10. Note that in some IC designs, the device layer 10 may include multiple layers of semiconductor devices. The devices of the device layer 10 are formed on or in the substrate 32 using various semiconductor processing operations such as dopant diffusion and/or implantation, etching, material deposition, and/or so forth. After the FEOL processing, back end-of-line (BEOL) processing is performed on the front side 14 of the device layer 10 (e.g., on the side 14 of the device layer 10 that is distal from the substrate 14) to form the metallization stack 12. Each layer of the metallization stack 12 is formed by deposition of a portion of the intermetal dielectric (IMD) layer 18, opening and filling via openings in (the portion of) the IMD layer to from vias passing through the IMD layer, depositing a metal layer on the IMD layer and patterning the metal layer to form a patterned metal layer 16, and repeating to form each metal layer 16 in succession. The vias through first IMD layer contact terminals of devices of the device layer 10. The resulting structure is diagrammatically shown in the sectional view of FIG. 2B.

To form the back side components, the substrate 32 is removed. To this end, with reference to FIG. 2C a carrier wafer 34 is bonded to the exposed upper surface of the metallization stack 12 by way of a suitable adhesive 36. By way of some nonlimiting illustrative examples, the carrier wafer 34 may comprise a silicon wafer, a sapphire wafer, or so forth. The adhesive 36 is a material providing a bond of sufficient strength between the carrier wafer 34 and the IMD 18. With reference to FIG. 2D, the assembly is shown in a flipped orientation, with the substrate 32 removed. The substrate removal can employ any suitable approach. In one nonlimiting illustrative example, the substrate 32 is a SOI wafer and the substrate removal entails removing the insulator layer (e.g., silicon dioxide in some SOI wafer designs) leaving the upper silicon layer of the SOI wafer on which the semiconductor devices are formed. In this example, the device layer 10 includes the devices and the remaining silicon layer of the SOI wafer. (That silicon layer may be of sub-micron thickness for some SOI wafers). In other contemplated approaches, the substrate 32 may be removed by a back side applied mechanical or chemical-mechanical thinning process. The resulting structure as shown in FIG. 2D includes the carrier wafer 34, the metallization stack 18 bonded to the carrier wafer 34 by the adhesive 36, and the device layer 10 with its back side 24 now exposed by the removal of the substrate 32. (Note again that FIG. 2D is showing the structure in flipped orientation compared with previous FIGS. 2A-2C).

With the back side 24 of the device layer 10 now exposed, the back side components can be fabricated. Formation of the back side power distribution network 20 depends on the architecture chosen, but typically entails processing similar to the BEOL processing, e.g., (repetitions of) depositing dielectric material, forming via openings and filling to form vias, and depositing and patterning metal layers. Similar processing is used to form the at least one transmission conductor 28. A damascene process (described in further detail later herein) may be used to form the vias 30 that connect with the at least one transmission conductor 28. In some embodiments disclosed later herein, a dual damascene process may be used to form both the vias 30 that connect with the at least one transmission conductor 28 and also the at least one transmission conductor 28 and/or a lowest metal layer of the back side power distribution network 20.

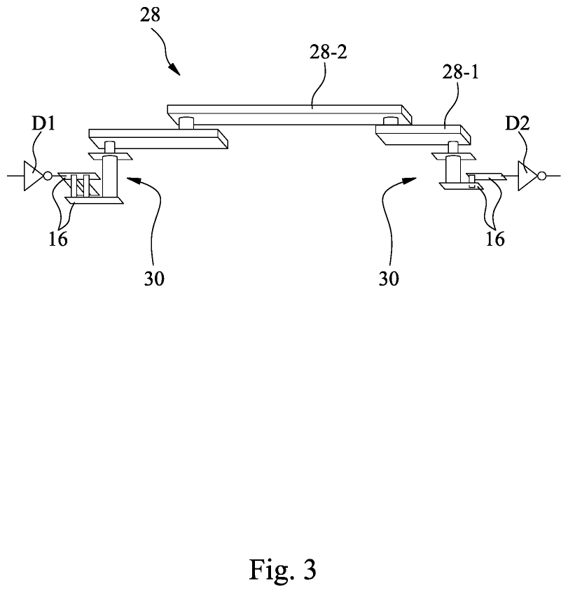

To further illustrate the features of the transmission conductor 28 and vias 30, FIG. 3 diagrammatically illustrates an isolation perspective view of the signal transmission conductor 28 disposed on the back side of the device layer 10 of an IC. In FIG. 3, two diagrammatically illustrated semiconductor devices D1 and D2 of the device layer are connected by the transmission conductor 28. More particularly, in this nonlimiting illustrative example the devices D1 and D2 are connected to the lowest two metal layers 16 of the metallization stack 12, and the vias 30 at one end connect with one of these metal layers 16 as shown, pass through the device layer 10 and at the opposite end connect with the transmission conductor 28. In illustrative FIG. 3, the transmission conductor 28 is itself made of two metal layers 28-1 and 28-2. Notably, the total transmission length is short, because it passes through only the lowest two metal layers 16 of the front side metallization stack 12 (which may have a dozen or more total metal layers in some more complex IC designs), through the copper vias 30, and through the transmission conductor 28 which itself includes only two layers 28-1 and 28-2 in this example. This is much shorter than the typical transmission length when only the metallization stack 12 is employed for signal transmission, because in that case the signal may need to be routed through many metal layers of the stack 12, especially if the signal needs to be transmitted a long distance (e.g., from a device near one edge of the IC area to a second device near the opposite edge of the IC area).

In the following, some nonlimiting illustrative examples of damascene processes for fabricating the copper vias 30 are described.

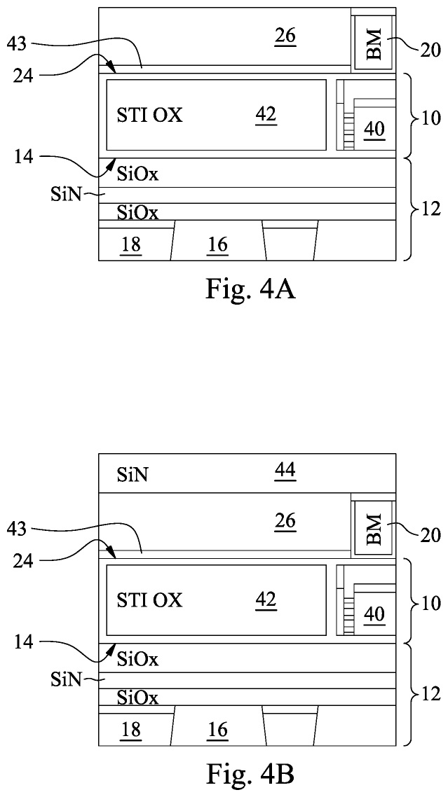

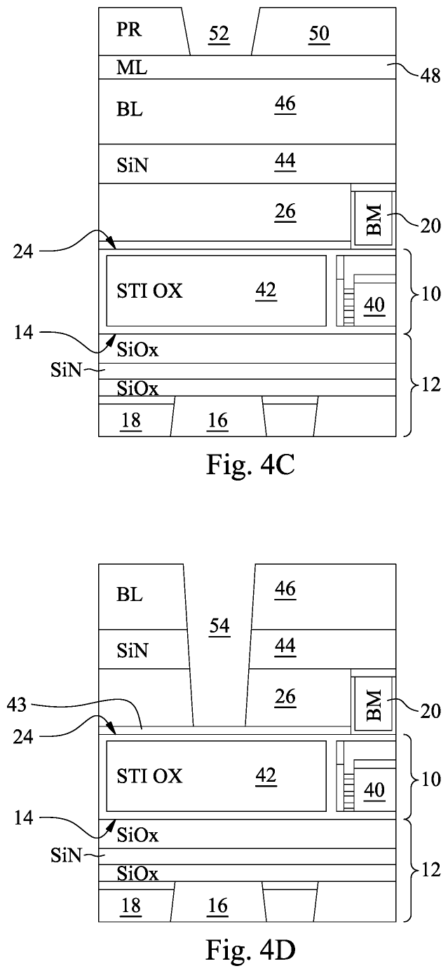

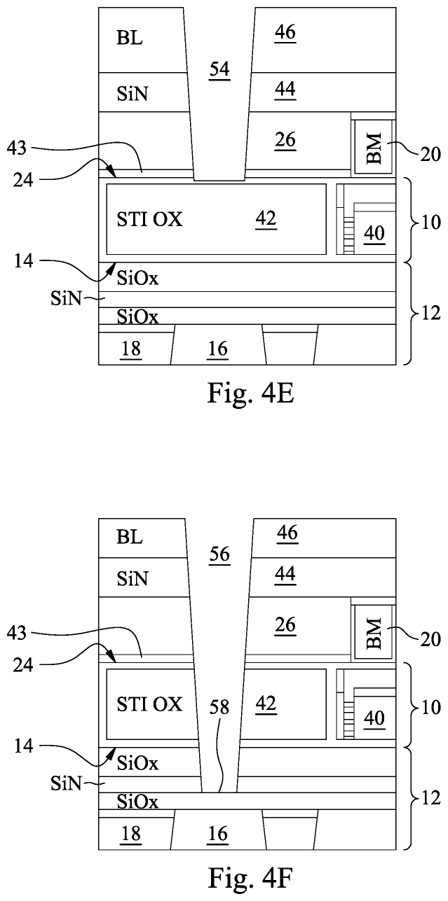

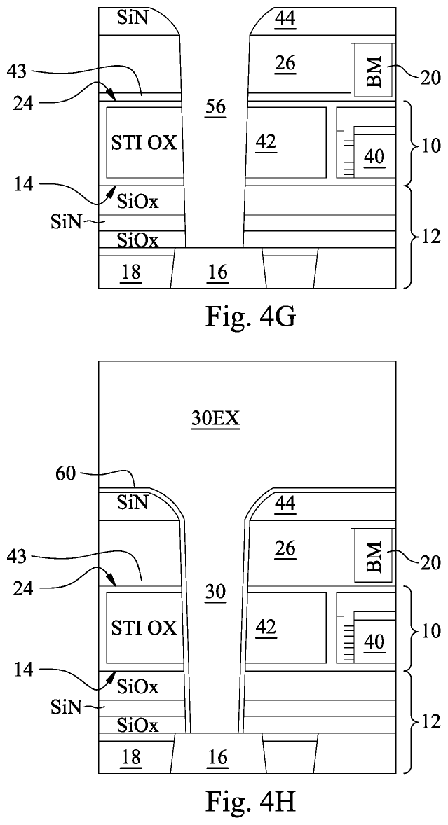

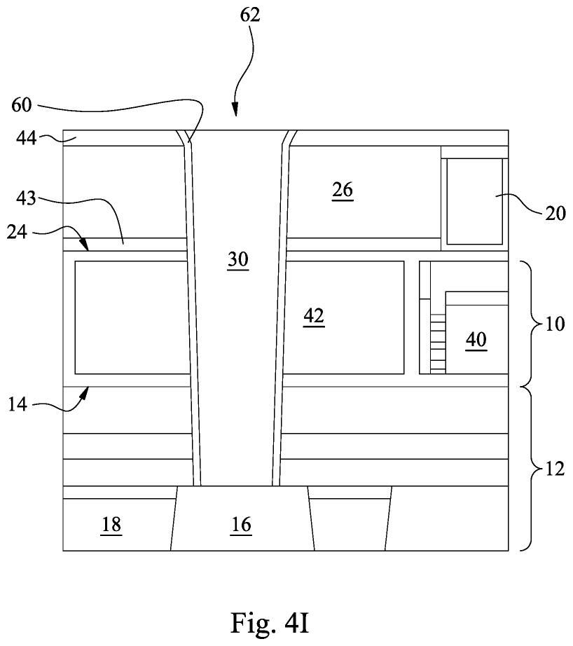

With reference to FIGS. 4A-4I, sectional views of successive stages of fabrication of a copper via by a damascene process according to a first embodiment are shown. FIG. 4A illustrates a portion of the IC corresponding to FIG. 2D (i.e., after removal of the substrate 32) and after deposition of a first layer of the back side dielectric material 26 and formation of a first layer of the back side power distribution network 20. As previously noted, the back side dielectric material 26 may, for example, be a low-k dielectric material. The device layer 10 is diagrammatically indicated by a portion of epitaxially grown material 40 and surrounding shallow trench isolation (STI) oxide material 42. The via is destined to be formed passing through the device layer 10, and more particularly through the STI region 42. It is also noted that while the epitaxial material 40 is shown to diagrammatically represent a semiconductor device 42 of the device layer 10, this is merely one nonlimiting illustrative example, and more generally the semiconductor devices of the device layer 10 could be fabricated in various ways, such as being formed of doped regions created by dopant implantation or dopant diffusion, regions of deposited polysilicon, and/or so forth. Note that the portion of the IC shown in FIGS. 4A-4I show only the first layer 16 of the metallization stack 12. The illustrative example of FIGS. 4A-4I also illustrate the dielectric layers comprising silicon oxide (SiOₓ) layers, and various etch stop layers (ESLs) such as (depending on the etchant) SiN, AlOₓ, ZrOₓ, AlN, and/or so forth. Different types of ESL may be used to provide etch stops at different depths using suitable material-selective etchants in accordance with the IC manufacturing workflow. As an example, the back side 24 of the device layer 10 has disposed therein an etch stop layer ESL) 43, such as AlOₓ, ZrOₓ, AlN, or so forth as some nonlimiting illustrative examples.

FIG. 4B illustrates the IC portion after deposition of a SiN layer 44 on the ESL 43. FIG. 4C illustrates the IC portion after deposition of a hard mask including a bottom layer (BL) 46 and a middle layer 48. In one nonlimiting illustrative embodiment, the bottom layer 46 is SiCO, although other materials are contemplated. In one nonlimiting illustrative embodiment, the middle layer 48 is SiCHO or amorphous carbon, although other materials are contemplated. A photoresist layer is applied to the middle layer 48 and photolithographically patterned (e.g., by exposing to light via a photomask to form a latent image in the photoresist followed by developing the photoresist) to form a patterned photoresist 50 with an opening 52 through which the via opening will be etched.

FIG. 4D illustrates the portion of the IC after further processing to form a partial via opening 54 which is a continuation of the opening 52 passing through the layers and stopping at the ESL layer 43 disposed on the back side 24 of the device layer 10. This can be done, for example, using a dry etch that etches the materials of the ML 48, BL 46, SiN 44, and back side dielectric material 26 but does not etch the ESL layer 43 disposed on the back side 24 of the device layer 10 (for example, an AlOₓ, ZrOₓ, or AlN layer as some nonlimiting examples). This processing also includes stripping the photoresist 50 and removing the middle layer 48, so that the bottom layer 46 serves as the mask for subsequent etch steps. FIG. 4E illustrates the portion of the IC after a further wet etch to remove the portion of the ESL layer 43 disposed at the bottom of the opening 54.

FIG. 4F illustrates the portion of the IC after further etching to extend the via opening 54 through the device layer 10 to complete formation of a complete via opening 56 landing on a patterned metal layer 16 of the metallization stack 12. Again, the bottom layer 46 serves as the mask for this etching (which may attack the bottom layer 46 enough to thin it, as diagrammatically shown in FIG. 4F). The etching through the STI 42 and the dielectric layers of the metallization stack 12 up to the patterned metal layer 16 may, for example, be performed using dry etching. However, this etching can leave residue 58 at the bottom of the via opening 56. Left in place, this residue 58 would undesirably increase electrical resistance at the interface between the copper via 30 (not yet formed at FIG. 4F) and the patterned metal layer 16. Hence, in a liner removal step (e.g., a suitable wet etch or the like), this residue 58 is removed or stripped, resulting in the IC as shown by the portion depicted in FIG. 4G in which the via opening 56 exposes a portion of the patterned metal layer 16. In some workflows, an after-stripping inspection (ASI) may be performed to verify removal of the residue 58. The structure at the stage of FIG. 4G thus has the via opening 56 fully formed. In accordance with a damascene process, this via opening 56 is then filled with copper by a copper plating process.

FIG. 4H illustrates the structure after the copper plating is complete. To protect the wall of the via opening 56 during the copper electroplating process, a thin layer 60 of a protective material such as tantalum (Ta), tantalum nitride (TaN), silicon nitride (SiN), silicon carbide (SiC), or so forth may optionally be applied to the wall of the via opening 56 before performing the copper electroplating. To perform the copper plating, a thin copper seed layer is applied, e.g. by physical vapor deposition (PVD), chemical vapor deposition (CVD), or another suitable technique, followed by the copper electroplating itself which electroplates copper on the seed layer. The copper electroplated in the copper via opening 56 forms the copper via (i.e., copper feed-through) 30. However, the electroplating is not confined to the via opening 56, but rather also plates copper 30EX on the SiN layer 44, thus plating the excess copper 30EX on the surface of the SiN layer 44 as seen in FIG. 4H. Hence, the copper electroplating is followed by chemical mechanical polishing (CMP) to remove the excess copper 30EX, resulting in the final copper via 30 as shown in FIG. 4I.

With continuing reference to FIG. 4I, the fabricated copper via 30 electrically contacts the patterned metal layer 16 of the metallization stack 12. The specific patterned metal layer that is contacted can vary; however, for minimal electrical resistance it is typically preferred to contact a patterned metal layer that is located near to the device layer 10 (e.g., metal layer M0 or M1, for example). Although not shown in FIG. 4I, an exposed end 62 of the copper via 30 will contact a signal transmission conductor 28 (not yet formed at the step shown in FIG. 4I, but see FIG. 2E and FIG. 3 and related discussion). As previously discussed, the signal transmission conductor 28 is disposed on the back side 24 of the device layer 10, and is embedded or disposed in the back side dielectric material 26 (seen in FIG. 2E). If the signal transmission conductor 28 is a copper transmission conductor, then an all-copper path is provided from the patterned metal layer 16 of the front side metallization stack 12 through the device layer 10 to the copper transmission conductor 28. As further seen in FIG. 2E, there are copper vias 30 at both ends of the copper transmission conductor 28, thus providing a low resistance signal transmission pathway. The path is all copper except for the thin layer 60 of the protective material (e.g., Ta, TaN, SiN, SiC, or so forth)—however, this thin layer 60 is typically only a few angstroms in thickness and may be of an electrically conductive material (e.g., Ta) and hence does not introduce significant additional electrical resistance.

The fabrication process of FIGS. 4A-4I is a damascene process, in which a via opening 56 is formed, copper is electroplated in the via opening 56 to form the copper via 30, and the excess copper 30EX is removed by chemical mechanical polishing. It is noted that the detailed sequence of etches in the damascene process for fabricating the copper vias 30 may be different from those described in the nonlimiting illustrative example of FIGS. 4A-4I, depending on factors such as the number, depths, and materials of the etch stop layers in the structure. In general, the damascene process enables formation of the copper via 30 with a relatively small diameter, e.g. 50-100 nanometers in diameter in some nonlimiting illustrative embodiments, thus facilitating miniaturization and being compatible with IC manufacturing workflows with small critical dimension sizes. It will also be appreciated that while FIGS. 4A-4I illustrate formation of a single copper via 30, the process may suitably form any number of copper vias 30 with suitable patterning of the photoresist 50, e.g. with an opening 52 located where each copper via 30 is to be formed.

More particularly, the fabrication process of FIGS. 4A-4I is a single damascene process which forms the via 30. Back side electrical conductors such the signal transmission conductor 28 and/or conductors of the back side power distribution network 20 are formed by another process, such as deposition and photolithographic patterning of blanket copper layers.

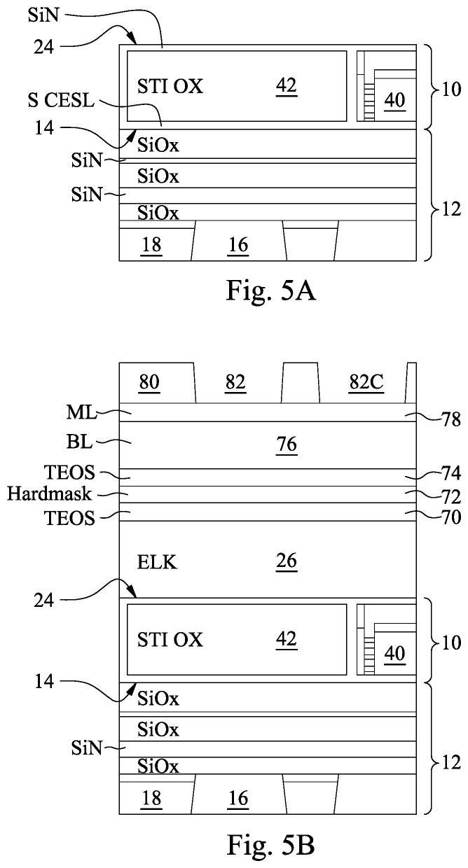

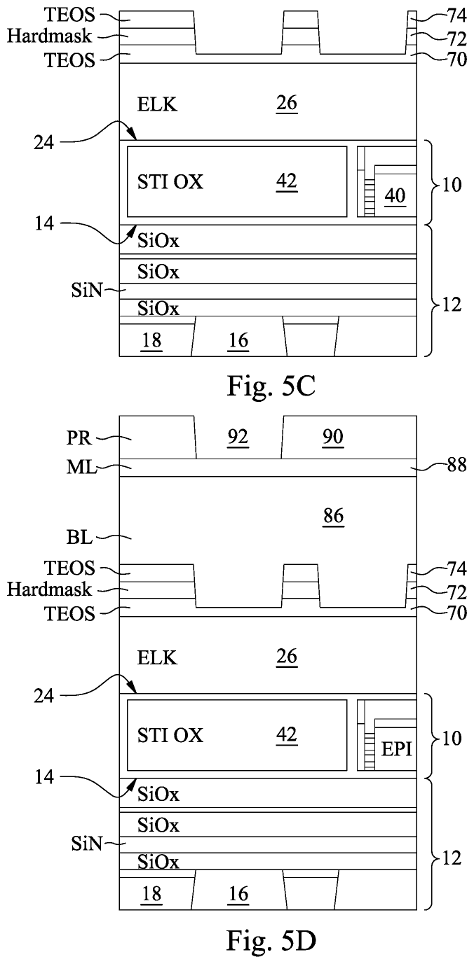

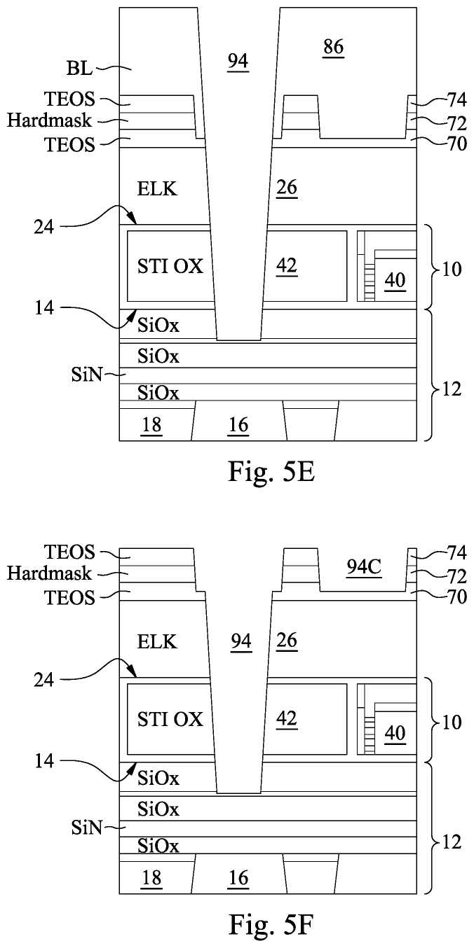

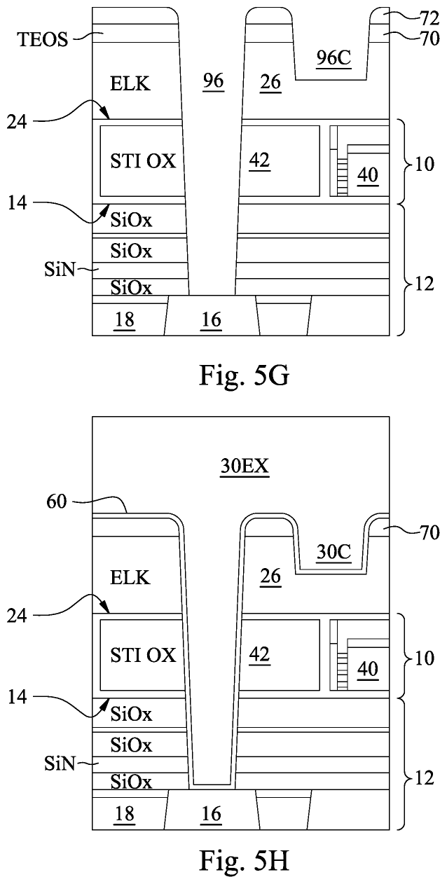

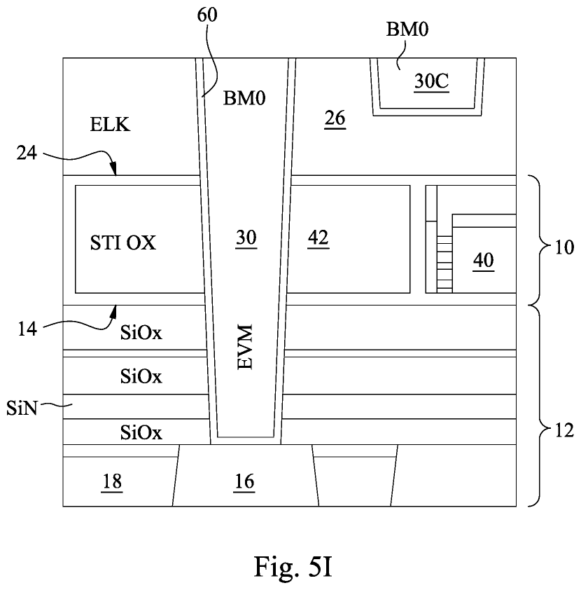

With reference to FIGS. 5A-5I, in some embodiments the copper vias 30 are formed by a dual damascene process which also forms a layer of electrical conductors 30C (see FIGS. 5H and 5I) which can serve as (a portion of) the back side electrical conductors, such as forming the signal transmission conductor 28 and/or conductors of the back side power distribution network 20. FIG. 5A illustrates a portion of an IC that is similar to that of FIG. 4A, except that the ESL 43 is not present, and at the stage shown in FIG. 5A no portion of the back side dielectric material 26 has yet been deposited. FIG. 5A illustrates the device layer 10 including the illustrative semiconductor device 40 and STI oxide 42, and the front side metallization stack 12 on the front side 14 of the device layer 10.

FIG. 5B illustrates the portion of the IC after formation of (a first layer of) the back side dielectric material 26 (which in this embodiment is an extremely low-k dielectric material, i.e., ELK dielectric, a layer of tetraethylorthosilicate (TEOS) 70, a hard mask 72, a second TEOS layer 74, a mask including a bottom layer 76, a middle layer 78, and patterned photoresist 80 with openings 82 and 82C formed therein. Note that unlike the (single) damascene process of FIGS. 4A-4I, in the dual damascene process of FIGS. 5A-5I both an opening 82 which will be used to form the copper via 30 and an opening 82C which will be used to form the copper conductor 30C are patterned in the photoresist. The bottom layer 76, middle layer 78, and patterned photoresist 80 can be formed analogously to the corresponding bottom layer 46, middle layer 48, and patterned photoresist 50 of the single damascene embodiment of FIG. 4C. Etching through the photoresist openings 82 and 82C transfers these openings to the TEOS 70/hard mask 72/TEOS 74 stack, and the mask layers 76, 78 and photoresist 80 are stripped thus producing the structure shown in FIG. 5C. It should be noted that while the photoresist opening 82 corresponding to the destined copper via 30 will typically be circular and/or of low aspect ratio, the photoresist opening 82C corresponding to the destined conductor 30C may in general comprise a large aspect ratio opening such as a trench, which may or may not be linear (e.g., the photoresist opening 82C could be curved or otherwise shaped in correspondence with the conductor 30C that is to be formed in the dual damascene process).

Next, a new mask comprising a bottom layer 86 and middle layer 88 and a patterned photoresist layer 90 are formed as shown in FIG. 5D. Here, the patterned photoresist layer 90 has only an opening 92 corresponding to the destined copper via 30, but not an opening corresponding to the destined copper conductor 30C.

A partial via opening 94 delineated by the photoresist opening 92 is etched, which penetrates through the device layer 10 and through a portion of the metallization stack 12, but does not reach the metal layer 16 of the front side metallization stack 12, as seen in FIG. 5E. This step also includes removal or stripping of the photoresist 90 and middle layer 88, leaving only the bottom layer 86, as further seen in FIG. 5E.

The bottom layer 86 is then removed, as shown in FIG. 5F. This is done by etching, and also exposes an opening 94C in the TEOS 70/hard mask 72/TEOS 74 stack which corresponds to the destined copper conductor 30C, as seen in FIG. 5F. Further etching is performed to further deepen the opening 94 to form the complete via opening 96 landing on the metal layer 16 of the front side metallization stack 12, as seen in FIG. 5G. As further seen in FIG. 5G, this etching deepens the opening 94C to form an opening 96C in the form of a trench 96C that will be filled with copper during the subsequent copper electroplating step to form the copper conductor 30C.

The copper plating is then performed as previously described, i.e., optionally depositing the thin layer 60 of a protective material (e.g., Ta, TaN, SiN, SiC, or so forth), depositing the thin copper seed layer by PVD, CVD, or another suitable technique, followed by the copper electroplating itself which electroplates copper on the seed layer. The copper electroplated in the copper via opening 96 forms the copper via (i.e., copper feed-through) 30, and the copper electroplated in the trench 96C forms the copper conductor 30C, and additionally excess copper 30EX forms on the upper surface, as seen in FIG. 5H. The copper electroplating is followed by chemical mechanical polishing (CMP) to remove the excess copper 30EX, resulting in the final copper via 30 and copper conductor 30C as shown in FIG. 5I.

As previously noted, the copper conductor 30C could in some embodiments serve as the least one signal transmission conductor 28. In such cases, with reference back to FIG. 5G the trench 96C may intersect with the via openings 96 and this combined structure electroplated to form each signal transmission conductor 28 and its terminating copper vias 30 as a single copper structure. This advantageously can improve mechanical robustness of the conductive structure and reduce electrical resistance.

In the illustrative embodiment, the back side signal transmission paths including the copper vias 30 and the at least one signal transmission conductor 28 are employed together with the back side power distribution network 20, both of which are disposed on the back side 24 of the device layer 10. This is advantageous because process steps for forming the back side power distribution network 20 may be able to be utilized in concurrently forming the copper vias 30 and/or the at least one signal transmission conductor 28, for example by modification of masks used in fabricating the back side power distribution network 20. However, it is also contemplated to employ the back side signal transmission paths including the copper vias 30 and the at least one signal transmission conductor 28 without also employing the back side power distribution network 20.

In the following, some further embodiments are described.

In a nonlimiting illustrative embodiment, a method of fabricating an integrated circuit is disclosed. The method comprises: forming a device layer comprising a plurality of electronic devices; forming a metallization stack on a front side of the device layer, the metallization stack including a plurality of patterned metal layers spaced apart by intermetal dielectric material, the patterned metal layers electrically interconnecting the electronic devices of the device layer; forming a back side power distribution network on a back side of the device layer, the back side power distribution network including at least one back side patterned metal layer connected with power terminals of the plurality of semiconductor devices of the device layer; and forming copper vias passing through the device layer and contacting at least one patterned metal layer of the metallization stack, the copper vias being formed by a damascene process. In some embodiments, the method further includes forming at least one signal transmission conductor disposed on the back side of the device layer and electrically connected with the copper vias.

In a nonlimiting illustrative embodiment, an integrated circuit comprises: a device layer comprising a plurality of electronic devices; a metallization stack disposed on a front side of the device layer and comprising a plurality of patterned metal layers spaced apart by intermetal dielectric material, the metallization stack electrically interconnecting the electronic devices of the device layer; a back side power distribution network disposed on a back side of the device layer and connected to deliver electrical power to the plurality of semiconductor devices of the device layer; at least one signal transmission conductor disposed on the back side of the device layer; and copper vias passing through the device layer, the copper vias electrically connecting the at least one signal transmission conductor with at least one patterned metal layer of the metallization stack.

In a nonlimiting illustrative embodiment, a method of fabricating an integrated circuit is disclosed. The method comprises: forming a device layer comprising a plurality of electronic devices; disposing at least one dielectric layer on the device layer; etching via openings passing through the at least one dielectric layer and through the device layer; electroplating copper on the at least one dielectric layer and filling the via openings, wherein the copper electroplated in the via openings form copper vias passing through the at least one dielectric layer and through the device layer and electrically connecting with devices of the device layer; and performing chemical mechanical polishing to remove the copper electroplated on the at least one dielectric layer. In some embodiments, the method further includes forming at least one signal transmission conductor disposed on the at least one dielectric layer and electrically connected with the copper vias.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of fabricating an integrated circuit, the method comprising:
forming a device layer comprising a plurality of electronic devices;
forming a metallization stack on a front side of the device layer, the metallization stack including a plurality of patterned metal layers spaced apart by intermetal dielectric material, the patterned metal layers electrically interconnecting the electronic devices of the device layer;
forming a back side power distribution network on a back side of the device layer, the back side power distribution network including at least one back side patterned metal layer connected with power terminals of the plurality of semiconductor devices of the device layer; and
forming copper vias passing through the device layer and contacting at least one patterned metal layer of the metallization stack, the copper vias being formed by a damascene process.

2. The method of claim 1, wherein the forming of the device layer includes forming the plurality of electronic devices on and/or in a front side of a semiconductor substrate, and the method further comprises:
bonding the metallization stack to a carrier substrate; and
removing the semiconductor substate to expose the back side of the device layer.

3. The method of claim 1, wherein the damascene process by which the copper vias are formed includes:
disposing at least one back side dielectric layer on the back side of the device layer;
etching via openings from the back side of the device layer and passing through the at least one back side dielectric layer and through the device layer, the etching of the via openings stopping on the at least one patterned metal layer of the metallization stack;
electroplating copper on the back side of the device layer and filling the via openings to form the copper vias passing through the device layer and contacting the at least one patterned metal layer of the metallization stack; and
performing chemical mechanical polishing to remove the copper electroplated on the back side of the device layer.

4. The method of claim 3, wherein the damascene process is a dual damascene process further including:
prior to the electroplating, etching trenches in the at least one back side dielectric layer, wherein the electroplating also fills the trenches to form a patterned metal layer of the back side power distribution network.

5. The method of claim 4, wherein the etching of the via openings and the etching of the trenches comprises:
performing a first etch that forms the trenches and partial via openings; and
performing a second etch that extends the partial via openings to stop on the at least one patterned metal layer of the metallization stack.

6. The method of claim 3, further comprising:
forming at least one signal transmission conductor disposed on the back side of the device layer and electrically connected with the copper vias by, prior to the electroplating, etching at least one trench in the at least one back side dielectric layer, wherein the electroplating also fills the at least one trench to form the at least one signal transmission conductor.

7. The method of claim 3, further comprising:
prior to disposing the at least one back side dielectric layer, disposing a back side etch stop layer on the back side of the device layer, wherein the etching of the via openings includes:
performing a first etch to form partial via openings that pass through the at least one back side dielectric layer and stop at the back side etch stop layer,
removing the portions of the back side etch stop layer disposed at bottoms of the partial vias; and
performing a second etch to extend the partial via openings to pass through the device layer and stop on the at least one patterned metal layer of the metallization stack.

8. The method of claim 1, further comprising:
forming at least one signal transmission conductor disposed on the back side of the device layer and electrically connected with the copper vias;
wherein the plurality of patterned metal layers of the metallization stack comprise patterned copper layers, and the at least one signal transmission conductor comprises at least one copper signal transmission conductor.

9. An integrated circuit comprising:
a device layer comprising a plurality of electronic devices;
a metallization stack disposed on a front side of the device layer and comprising a plurality of patterned metal layers spaced apart by intermetal dielectric material, the metallization stack electrically interconnecting the electronic devices of the device layer;
a back side power distribution network disposed on a back side of the device layer and connected to deliver electrical power to the plurality of semiconductor devices of the device layer;
at least one signal transmission conductor disposed on the back side of the device layer; and
copper vias passing through the device layer, the copper vias electrically connecting the at least one signal transmission conductor with at least one patterned metal layer of the metallization stack.

10. The integrated circuit of claim 9, wherein the at least one signal transmission conductor comprises copper.

11. The integrated circuit of claim 10, wherein the at least one patterned metal layer of the metallization stack comprises copper.

11. The integrated circuit of claim 11, wherein metallization stack, the copper vias, and the at least one signal transmission conductor form at least one all-copper signal transmission path between devices of the device layer.

12. The integrated circuit of claim 9, wherein the copper vias are coated with a copper diffusion barrier layer.

13. The integrated circuit of claim 12, wherein the copper diffusion barrier layer comprises cobalt or tantalum nitride (TaN).

14. The integrated circuit of claim 9, further comprising:
a back side dielectric layer disposed interposed between the back side of the device layer and the at least one signal transmission conductor, the copper vias also passing through the back side dielectric layer.

15. A method of fabricating an integrated circuit, the method comprising:
forming a device layer comprising a plurality of electronic devices;
disposing at least one dielectric layer on the device layer;
etching via openings passing through the at least one dielectric layer and through the device layer;
electroplating copper on the at least one dielectric layer and filling the via openings, wherein the copper electroplated in the via openings form copper vias passing through the at least one dielectric layer and through the device layer and electrically connecting with devices of the device layer; and
performing chemical mechanical polishing to remove the copper electroplated on the at least one dielectric layer.

16. The method of claim 15, further comprising:
forming a metallization stack on the device layer wherein the device layer is interposed between the metallization stack and the at least one dielectric layer;
wherein the via openings passing through the at least one dielectric layer and through the device layer land on at least one patterned metal layer of the metallization stack.

17. The method of claim 15, further comprising:
forming a power distribution network on the at least one dielectric layer.

18. The method of claim 17, further comprising:
prior to the electroplating, etching trenches in the at least one dielectric layer, wherein the electroplating also fills the trenches to form a patterned metal layer of the power distribution network.

19. The method of claim 15, further comprising:
forming at least one signal transmission conductor disposed on the at least one dielectric layer and electrically connected with the copper vias.

20. The method of claim 15, further comprising:
prior to disposing the at least one dielectric layer, disposing an etch stop layer on the device layer, wherein the etching of the via openings includes performing a first etch to form partial via openings that pass through the at least one dielectric layer and stop at the etch stop layer, removing the portions of the etch stop layer disposed at bottoms of the partial vias; and performing a second etch to extend the partial via openings to pass through the device layer.
